(19) United States
(12) Patent Application Publication
(10) Pub. No.: US 2010/0015356 A1
(43) Pub. Date: Jan. 21, 2010

(54) IN-LINE FILM FORMING APPARATUS AND MANUFACTURING METHOD OF MAGNETIC RECORDING MEDIUM

(75) Inventors: Masato FUKUSHIMA, Chiba-shi (JP); Akira Sakawaki, Ichihara-shi (JP); Tomoo Shige, Chiba-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Tokyo (JP)

(21) Appl. No.: 12/498,051

(22) Filed: Jul. 6, 2009

(30) Foreign Application Priority Data
Jul. 10, 2008 (JP) 2008-180494

(51) Int. Cl. C23C 16/453; C23C 14/34

(52) U.S. Cl. 427/569; 118/718; 204/298.15; 204/192.2

(57) ABSTRACT

An in-line film forming apparatus is provided which prevents uneven processing from occurring when reactive plasma treatment or ion irradiation treatment is performed on a substrate held by a carrier. A carrier (25) includes a holder (28) provided with a hole (29) which allows a substrate to be disposed therein, and a plurality of supporting members (30) attached to the periphery of the hole (29) of the holder (28) in an elastically deformable manner, and is capable of detachably holding the substrate fitted into the inside of the supporting members (30) while an outer peripheral portion of the substrate is made to abut on the plurality of supporting members (30). Within a chamber which performs reactive plasma treatment or ion irradiation treatment on the substrate held by the carrier (25), a ring member (32) having an opening (32a) in a position corresponding to the substrate is disposed so as to face at least one surface or both surfaces of the substrate held by the carrier (25). Negative potential is applied to the ring member (32), and the holder (28) is grounded.

### CROSS REFERENCE TO RELATED APPLICATION

Priority is claimed on Japanese Patent Application No. 2008-180494, filed Jul. 10, 2008, the content of which is incorporated herein by reference.

### BACKGROUND OF THE INVENTION

1. Field of the Invention

The present invention relates to an in-line film forming apparatus which performs film forming processing while a substrate held by a carrier is sequentially conveyed between a plurality of film forming chambers, and a manufacturing method of a magnetic recording medium using the inline film forming apparatus.

2. Description of the Related Art

In recent years, the range of application of magnetic recording apparatuses, such as magnetic disk apparatuses, flexible disk apparatuses, and magnetic tape apparatuses, has increased remarkably, and as the importance of the apparatuses increases, remarkable improvements in the recording density of magnetic recording media used for the apparatuses are being promoted. In particular, since the introduction of an MR head or a PRML technique, the rise in surface recording density further increases severity. In recent years, a GMR head, a TMR head, or the like has also been introduced, and the surface recoding density continues to increase at a rate of about 100% per year.

As for these magnetic recording media, it is required that a high recording density is further attained from now on. For this reason, it is required that the high coercive force, high signal pair noise ratio (SNR), and high resolution of a magnetic layer are attained. Additionally, in recent years, the effort to raise the surface recording density by an increase in track density simultaneously with an improvement in track recording density is also continued.

In the newest magnetic recording apparatus, the track density reaches even 110 kTPI. However, if the track density is raised, the magnetic recording information between adjoining tracks interfere each other, and a magnetization transition region which is a boundary region becomes a noise source. As a result, the problem of damaging SNR easily occurs. Since this directly leads to a decrease in bit error rate, an improvement in recording density is hindered.

In order to raise the surface recording density, it is necessary to make the size of each recording bit on a magnetic recording medium finer, and to secure saturated magnetization and magnetic film thickness which are as large as possible for each recording bit. On the other hand, if the recording bit is made fine, the minimum magnetization volume per bit becomes small. As a result, the problem that recording data disappear due to the magnetization reversal by heat fluctuation will occur.

Additionally, if the track density is raised the distance between tracks decreases. Therefore, in the magnetic recording apparatus, an extremely high-precision track servo technique is required, and simultaneously, a method of executing recording widely and executing reproduction more narrowly than during recording in order to exclude the influence from an adjacent track as much as possible is generally used. However, in this method, the influence between adjacent tracks can be suppressed to the minimum, whereas there is a problem in that it is difficult to sufficiently obtain a reproducing output, and it is consequently difficult to secure a sufficient SNR.

As one of the methods which solve such a problem of heat fluctuation, securing the SNR, and securing the sufficient output, an attempt to raise the track density is made by forming irregularities along the tracks on the surface of a recording medium and physically separating the recording tracks. Such a technique is generally referred to as a discrete track method, and a magnetic recording medium manufactured by the technique is referred to as a discrete track medium. Additionally, an attempt to manufacture a so-called patterned media in which a data area in the same track is further divided is also made.

As an example of a discrete track medium, there is known a magnetic recording medium obtained by forming a magnetic recording medium on a nonmagnetic substrate on the surface of which a rugged pattern is formed and forming magnetic recording tracks and servo signal patterns which are physically separated (see Patent Document 1).

This magnetic recording medium is one in which a ferromagnetic layer is formed on the surface of a substrate which has a plurality of irregularities on the surface thereof via a soft magnetic layer, and a protective film is formed on the surface of the ferromagnetic layer. In this magnetic recording medium, a magnetic recording area which is physically divided from the surroundings is formed in a convex portion.

According to this magnetic recording medium, since the generation of a domain wall in the soft magnetic layer can be suppressed, the influence of the heat fluctuation hardly occurs, and there is no interference between adjacent signals. Thus, a high-density magnetic recording medium with less noise can be formed.

As the discrete track method, there is a method of forming tracks after a magnetic recording medium composed of several layers of thin films is formed, and a method of forming thin films of a magnetic recording medium after a rugged pattern is formed directly on the surface of a substrate in advance or on a thin film layer for the formation of tracks (see Patent Documents 2 and 3).

Additionally, a method of injecting ions of nitrogen, oxygen, or the like into a magnetic layer which is formed in advance, or irradiating the magnetic layer with laser beams, thereby changing the magnetic properties of the portion of the magnetic layer to form a region between the magnetic tracks of a discrete track medium is disclosed (see Patent Documents 4 to 6).

Additionally, as a manufacturing method of a discrete track medium, for example, there is a method of forming a soft magnetic layer, an interlayer, a recording magnetic layer, etc. on a nonmagnetic substrate, forming a mask layer for forming a magnetic recording area on the surface thereof by using photolithography, exposing the region of the recording magnetic layer which is not covered with the mask layer to the reactive plasma or the like, thereby reforming the magnetic properties of this region, removing the mask layer, and forming a protective layer and a lubricating layer.

In this manufacturing method, it is preferable to continuously perform the above steps using one film forming apparatus if possible in that a substrate is prevented from being contaminated when the substrate is handled, the number of handling steps and the like can be reduced to enhance the efficiency of the manufacturing process, and the yield of products can be improved to enhance the productivity of the magnetic recording media.

Thus, a method using an in-line film forming apparatus which sequentially forms a soft magnetic layer, an interlayer, a recording magnetic layer, and a protective layer on both surfaces of a plurality of nonmagnetic substrates while a carrier holding the plurality of nonmagnetic substrates are sequentially conveyed between a plurality of chambers when such a discrete track medium is manufactured is suggested (see Patent Document 7).

[Patent Document 1] Japanese Patent Unexamined Publication No. 2004-164692

[Patent Document 2] Japanese Patent Unexamined Publication No. 2004-178793

[Patent Document 3] Japanese Patent Unexamined Publication No. 2004-178794

[Patent Document 4] Japanese Patent Unexamined Publication No.5-205257

[Patent Document 5] Japanese Patent Unexamined Publication No. 2006-209952

[Patent Document 6] Japanese Patent Unexamined Publication No. 2006-309841

[Patent Document 7] Japanese Patent Unexamined Publication No. 8-274142

### SUMMARY OF THE INVENTION

Meanwhile, when a discrete track medium is manufactured using the above-described in-line film forming apparatus, a method of forming a recording magnetic layer, providing a mask layer on the surface of the recording magnetic layer, performing a reactive plasma treatment or ion irradiation treatment on the region which is not covered with the mask layer, thereby reforming the magnetic properties of a portion of the recording magnetic layer, and forming of a magnetic recording pattern made of the remaining magnetic body is performed.

However, in such an in-line film forming apparatus, uneven processing may occur when the reactive plasma treatment or ion irradiation treatment is performed on the recording magnetic layer of the nonmagnetic substrate held by the carrier.

Specifically, a conventional carrier 400 shown in FIG. 15 includes a holder 401 provided with a hole 401 a which disposes a nonmagnetic substrate D therein, and a plurality of supporting members 402 attached to the periphery of the hole 401a of the holder 401 in an elastically deformable manner. In the carrier 400, a nonmagnetic substrate D fitted into the inside of the supporting members 402 can be detachably held while the outer peripheral portion of the nonmagnetic substrate D is made to abut on the plurality of supporting members 402.

The uneven processing described above occurs near the outer periphery of the nonmagnetic substrate D which abuts the supporting members 402. It is considered that the reason is as follows. That is, the above-described reactive plasma treatment or ion irradiation treatment is performed by accelerating ions generated by a plasma generator within a chamber to make them collide against a nonmagnetic substrate to which a negative potential is applied. However, since the negative potential is supplied via the plurality of supporting members which abut the outer peripheral portion of the nonmagnetic substrate D, contact resistance occurs between the nonmagnetic substrate D and the supporting members, distribution occurs in a bias voltage to be applied to the nonmagnetic substrate, and arcing occurs in a contact portion.

Thus, the invention is suggested in order to solve such a conventional problem, and the object thereof is to provide an in-line film forming apparatus which prevents the occurrence of uneven processing when the reactive plasma treatment or ion irradiation treatment is performed on a substrate held by a carrier.

Additionally, the object of the invention is to provide a manufacturing method of a magnetic recording medium, which can, using such an in-line film forming apparatus, enhance the productivity of magnetic recording media, and prevent the occurrence of uneven processing when the reactive plasma treatment or ion irradiation treatment is performed on a recording magnetic layer of a nonmagnetic substrate held by a carrier, thereby enabling a further improvement in the quality of a magnetic recording medium which has a magnetic recording pattern, such as a discrete track medium.

The invention provides the following means.

(1) An in-line film forming apparatus includes a plurality of chambers which perform the film forming processing, a carrier which holds a substrate to be used as an object to be film-formed within the plurality of chambers, and a conveyor mechanism which conveys the carrier sequentially between the plurality of chambers. The carrier has a holder provided with a hole which allows the substrate to be disposed therein, and a plurality of supporting members attached to the periphery of the hole of the holder in an elastically deformable manner, and is capable of detachably holding the substrate fitted into the inside of the supporting members while an outer peripheral portion of the substrate is made to abut the plurality of the supporting members. At least one of the plurality of chambers is a chamber which performs the reactive plasma treatment or ion irradiation treatment on the substrate held by the carrier, and a ring member having an opening in a position corresponding to the substrate is disposed within the chamber so as to face at least one surface or both surfaces of the substrate held by the carrier. Negative potential is applied to the ring member, and the holder is grounded.

(2) The in-line film forming apparatus set forth in the above (1) in which a mesh member which covers the opening is attached to the ring member.

(3) The in-line film forming apparatus set forth in the above (1) or (2) in which the tip of each of the plurality of supporting members is provided with a groove engaged with the outer peripheral portion of the substrate.

(4) A manufacturing method of a magnetic recording medium forms at least a soft magnetic layer, an interlayer, and a recording magnetic layer, and a protective layer sequentially on both surfaces of a nonmagnetic substrate while the nonmagnetic substrate held by the carrier is conveyed through the plurality of chambers sequentially, using the in-line film forming apparatus set forth in any one of the above (1) to (3). The manufacturing method includes the step of applying a negative potential to the ring member in a chamber which performs the reactive plasma treatment or ion irradiation treatment after the recording magnetic layer is formed as a film, and performing the reactive plasma treatment or ion irradiation treatment on the recording magnetic layer of the nonmagnetic substrate held by the holder in a state where the holder is grounded, thereby reforming the magnetic properties of a portion of the recording magnetic layer, and forming a magnetic recording pattern made of the remaining magnetic body.

As described above, according to the invention, it is possible to provide an in-line film forming apparatus which prevents an occurrence of uneven processing when the reactive plasma treatment or ion irradiation treatment is performed on a substrate held by the carrier. Accordingly, when such an in-line film forming apparatus is used, it is possible to enhance the productive capacity of the magnetic recording media, and it is possible to manufacture high-quality magnetic recording media.

### BRIEF DESCRIPTION OF THE DRAWINGS

FIG. 1 is a sectional view showing an example of a magnetic recording medium manufactured by applying the invention.

FIG. 2 is a sectional view showing another example of a magnetic recording medium manufactured by applying the invention.

FIG. 3 is a perspective view showing an example of a magnetic recording and reproducing apparatus.

FIG. 4 is a plan view showing the configuration of an in-line film forming apparatus to which the invention is applied.

FIG. 5 is a side view showing a carrier of the in-line film forming apparatus to which the invention is applied.

FIG. 6 is a side view showing essential parts of the in-line film forming apparatus to which the invention is applied.

FIG. 7 is a sectional view showing essential parts of the in-line film forming apparatus to which the invention is applied.

FIG. 8 is a plan view showing substrates held by a carrier and a ring member.

FIG. 9 is a plan view showing a configuration in which a mesh member is attached to the ring member.

FIG. 10 is a cross-sectional schematic view showing a manufacturing method of a magnetic recording medium which is an embodiment of the invention in the order of steps.

FIG. 11 is a cross-sectional schematic view showing the manufacturing method of a magnetic recording medium which is the embodiment of the invention in the order of steps.

FIG. 12 is a cross-sectional schematic view showing the manufacturing method of a magnetic recording medium which is the embodiment of the invention in the order of steps.

FIG. 13 is an optical microscope photograph obtained by photographing a magnetic recording medium of Example 1.

FIG. 14 is an optical microscope photograph obtained by photographing a magnetic recording medium of Comparative Example 1.

FIG. 15 is a side view showing a carrier of a conventional in-line film forming apparatus.

### DETAILED DESCRIPTION OF THE INVENTION

Hereinafter, an embodiment of the invention will be described in detail with reference to the drawings. In this embodiment, a case where a magnetic recording medium mounted on a hard disk device is manufactured using an in-line film forming apparatus which performs film forming processing while a substrate which becomes an object to be film-formed is sequentially conveyed between a plurality of film forming chambers will be described as an example.

(Magnetic Recording Medium)

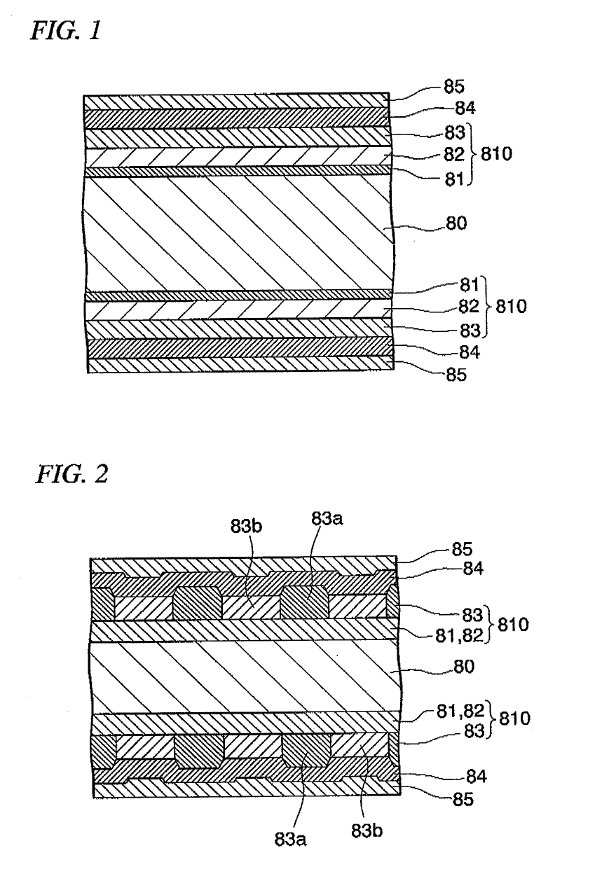

For example, as shown in FIG. 1, a magnetic recording medium manufactured by applying the invention has a structure where a soft magnetic layer 81, an interlayer 82, a recording magnetic layer 83, and a protective layer 84 are sequentially laminated on both surfaces of a nonmagnetic substrate 80, and further has a lubricating layer 85 formed on the outermost surface thereof. Additionally, a magnetic layer 810 is constituted by the soft magnetic layer 81, the interlayer 82, and the recording magnetic layer 83.

As the nonmagnetic substrate 80, arbitrary substrates can be used if they are Al alloy substrates made of, for example, an Al-Mg alloy and the like, which are composed mainly of aluminum, or nonmagnetic substrates, such as substrates made of normal soda glass, aluminosilicate-based glass, crystallized glass, silicone, titanium, ceramics, and various resins.

Among them, it is preferable to use Al alloy substrates, glass substrates, such as crystallized glass, and silicon substrates, Additionally, the average surface roughness (Ra) of these substrates is preferably equal to or less than 1 nm, and more preferably equal to or less than 0.5 nm. Among these, it is particularly preferable that the average surface roughness be equal to or less than 0.1 nm.

Although an in-plane magnetic layer for an in-plane magnetic recording medium or a perpendicular magnetic layer for a perpendicular magnetic recording medium is sufficient as the magnetic layer 810, the perpendicular magnetic layer is preferable in order to realize higher recording density. Additionally, it is preferable that the magnetic layer 810 be formed from alloys composed mainly of Co. For example, as the magnetic layer 810 for a perpendicular magnetic recording medium, a magnetic layer in which the soft magnetic layer 81 made of, for example, soft magnetic FeCo alloys (FeCoB, FeCoSiB, FeCoZr, FeCoZrB, FeCoZrBCu, etc.), FeTa alloys (FeTaN, FeTaC, etc.), Co alloys (CoTaZr, CoZrNB, CoB, etc.), etc., the interlayer 82 made of Ru, etc., and the recording magnetic layer 83 made of a 60Co-15Cr-15Pt alloy or a 70Co-5Cr-15Pt-10SiO₂ alloy are laminated can be utilized. Additionally, an alignment control film made of Pt, Pd, NiCr, NiFeCr, etc. may be laminated between the soft magnetic layer 81 and the interlayer 82. On the other hand, a magnetic layer in which a nonmagnetic CrMo foundation layer and a ferromagnetic CoCrPtTa magnetic layer are laminated can be utilized as the magnetic layer 810 for an in-plane magnetic recording medium.

The thickness of the whole magnetic layer 810 may be set to be equal to or more than 3 nm and equal to or less than 20 nm, more preferably, equal to or more than 5 nm and equal to or less than 15 nm, and the magnetic layer 810 may be formed so that a sufficient head in/out force is obtained in accordance with the kind and laminated structure of a magnetic alloy to be used. The film thickness of the magnetic layer 810 needs the film thickness of a magnetic layer of a certain value or more to obtain the output of a fixed value or more during reproduction. Since all the parameters which show recording/reproducing characteristics usually deteriorate with a rise in output, it is necessary to set the above film thickness to an optimal film thickness.

As the protective layer 84, carbonaceous layers, such as carbon (C), hydrogenated carbon (HₓC), nitrogenated carbon (CN), amorphous carbon, and silicon carbide (SiC), or protective layer materials, which are usually used, such as SiO₂, Zr₂O₃, and TiN, can be used. Additionally, the protective layer 84 may be composed of two or more layers. The film thickness of the protective layer 84 needs to be less than 10 nm. This is because, if the film thickness of the protective layer 84 exceeds 10 nm, the distance between a head and the recording magnetic layer 83 becomes large, and sufficient input/output signal intensity is not obtained.

As the lubricant used for the lubricating layer 85, fluorine-based lubricant, hydrocarbon-based lubricant, and mixtures thereof can be exemplified, and the lubricating layer 85 is usually formed with a thickness of 1 to 4 nm.

Additionally, for example, as shown in FIG. 2, the magnetic recording medium manufactured by applying the invention is a so-called discrete magnetic recording medium in which a magnetic recording pattern 83a formed in the above recording magnetic layer 83 is separated by nonmagnetic regions 83b.

Additionally, with regard to the discrete magnetic recording medium, so-called patterned media in which the magnetic recording pattern 83a is arranged with fixed regularity per one bit, or media in which the magnetic recording pattern 83a is arranged in the shape of a track, and other magnetic recording patterns 83a may include, for example, a servo signal pattern.

Such a discrete magnetic recording medium is obtained by providing a mask layer on the surface of he recording magnetic layer 83, exposing a portion which is not covered with the mask layer to the reactive plasma treatment, ion irradiation treatment, and so on, hereby reforming magnetic properties of a portion of the recording magnetic layer 83, preferably, reform a portion of the recording magnetic layer from a magnetic body into a nonmagnetic body to form the nonmagnetic regions 83b.

(Magnetic Recording and Reproducing Apparatus)

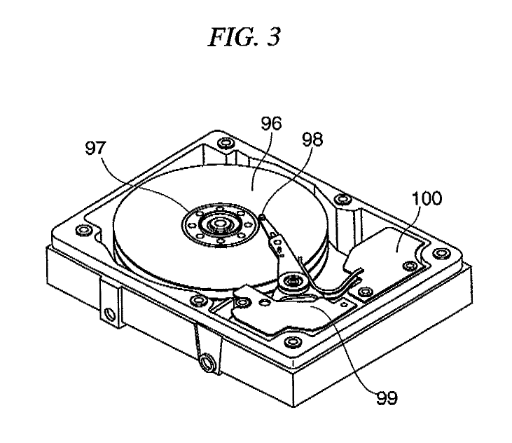

Additionally, a magnetic recording and reproducing apparatus using the above magnetic recording medium can be exemplified by, for example, a hard disk device as shown in FIG. 3. The hard disk device includes a magnetic disk 96 which is the above magnetic recording medium, a medium driving unit 97 which rotationally drives the magnetic disk 96, a magnetic head 98 which records/reproduces information on/from the magnetic disk 96, a head driving unit 99, and a magnetic reproducing signal processing system 100. The magnetic reproducing signal processing system 100 processes input data to send a recording signal to the magnetic head 98, and processes a reproduced signal from the magnetic head 98 to output data.

(In-Line Film Forming Apparatus)

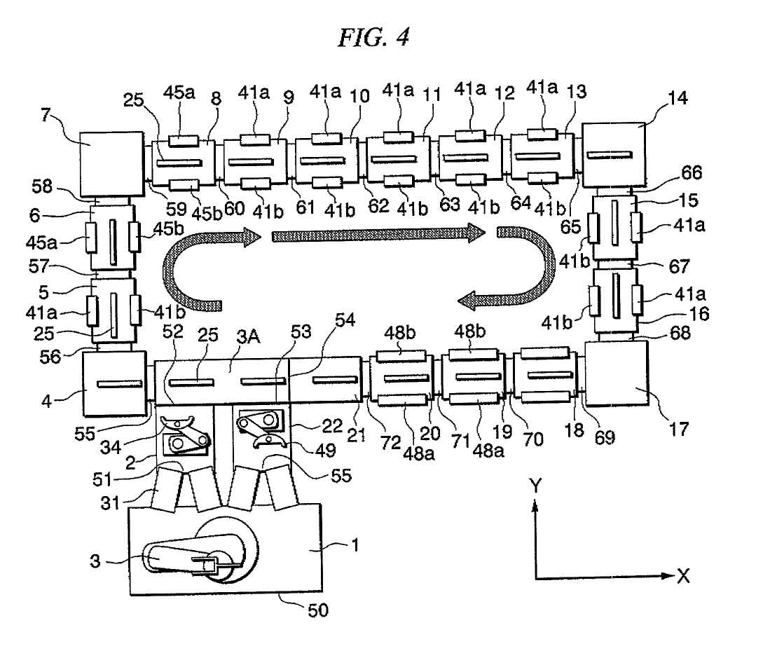

When the above magnetic recording medium is manufactured, for example, as shown in FIG. 4, high-quality magnetic recording media can be stably obtained using the in-line film forming apparatus (manufacturing apparatus of a magnetic recording medium) to which the invention is applied by passing through the steps of forming the magnetic layer 810 by sequentially laminating at least the soft magnetic layer 81, the interlayer 82, the recording magnetic layer 83, and the protective layer on both surfaces of the nonmagnetic substrate 80 serving as an object to be film-formed, forming the protective layer 84, and forming the lubricating layer 85 on the protective layer.

Specifically, the in-line film forming apparatus to which the invention is applied roughly has a robot base 1, a substrate cassette transfer robot 3 placed on the robot base 1, a substrate supply robot chamber 2 adjacent to the robot base 1, a substrate supply robot 34 arranged within the substrate supply robot chamber 2, a substrate attachment chamber 52 adjacent to the substrate supply robot chamber 2, corner chambers 4, 7, 14, and 17 which rotate a carrier 25, a plurality of chambers 5, 6, 8 to 13, 15, 16, and 18 to 20 arranged between the respective corner chambers 4, 7, 14, and 17, a substrate detachment chamber 54 arranged adjacent to the chamber 20, an ashing chamber 3A arranged between the substrate attachment chamber 52 and the substrate detachment chamber 54, a substrate detachment robot chamber 22 arranged adjacent to the substrate detachment chamber 54, a substrate detachment robot 49 set within the substrate detachment robot chamber 22, and a plurality of carriers 25 conveyed between the respective chambers.

Additionally, the respective chambers 2, 52, 4 to 20, 54, and 3A are each connected to two adjacent wall portions, and connecting portions of the respective chambers 2, 52, 4 to 20, 54, and 3A are provided with gate valves 55 to 71. When the gate valves 55 to 71 are in a closed state, the inside of each chamber becomes an independent enclosed space.

Additionally, vacuum pumps (not shown) are connected to the chambers 2, 52,4 to 20, 54, and 3A, respectively. A magnetic recording medium shown in the above FIG. 1 is finally obtained by sequentially film-forming the above-described soft magnetic layer 81, interlayer 82, recording magnetic layer 83, and protective layer 84 on both surfaces of the nonmagnetic substrate 80 held by each carrier 25 within each chamber while the carriers 25 are sequentially conveyed to the interiors of the respective chambers which are brought into a pressure-reduced state by the operation of these vacuum pumps by a conveyor mechanism which will be described later. Additionally, each of the corner chambers 4, 7, 14, and 17 is a chamber where the movement direction of each carrier 25 is changed, and the inside of the chamber is provided with a mechanism which rotates the carrier 25 to move the carrier to the next chamber.

The substrate cassette transfer robot 3 supplies the nonmagnetic substrate 80 to the substrate attachment chamber 2 from a cassette in which the nonmagnetic substrate 80 before film formation is received, and removes the nonmagnetic substrate 80 (magnetic recording medium) after the film formation detached in the substrate detachment chamber 22. An opening opened to the outside and a gate valve 51 or 55 which opens and doses this opening are provided at one side wall of the substrate attachment/detachment chamber 2 or 22.

Inside the substrate attachment chamber 52, the nonmagnetic substrate 80 before film formation is held by the carrier 25 by using the substrate supply robot 34. On the other hand, inside the substrate detachment chamber 54, the nonmagnetic substrate 80 (magnetic recording medium) after the film formation held by the carrier 25 is detached using the substrate detachment robot 49. The ashing chamber 3A makes the carrier 25 conveyed to the substrate attachment chamber 52 after ashing of the carrier 25 conveyed from the substrate detachment chamber 54 is performed.

Patterning chambers are constituted by the chambers 6 and 8 among the plurality of chambers 5, 6, 8 to 13, 15, 16, and 18 to 20. The patterning chambers are equipped with a mechanism which patterns a mask layer. Meanwhile, reforming chambers are constituted by the chambers 10, 11, and 12. Each reforming chamber is equipped with a mechanism which performs reactive plasma treatment or ion irradiation treatment on the region of the recording magnetic layer 83 which is not covered with a mask layer after patterning, thereby reforming the region into a nonmagnetic body and forming a magnetic recording pattern 83a made of the remaining magnetic body. Meanwhile, removal chambers are constituted byte chambers 16 and 18. The removal chambers are equipped with a mechanism which removes a mask layer. Meanwhile, the protective layer forming chambers are constituted by the chambers 19 and 20. The protective layer forming chambers are equipped with a mechanism which forms the protective layer 84 on the recording magnetic layer 83.

Additionally, the respective chambers 5, 6, 8 to 13, 15, 16, and 18 to 20 is provided with a processing gas supply pipes, and the processing gas supply pipes are provided with valves whose opening and closing are controlled by a control mechanism which is not shown. By operating to open and close these valves and the gate valves for pumps, the supply of gas from the processing gas supply pipes, the pressure within the chambers, and the discharge of gas are controlled.

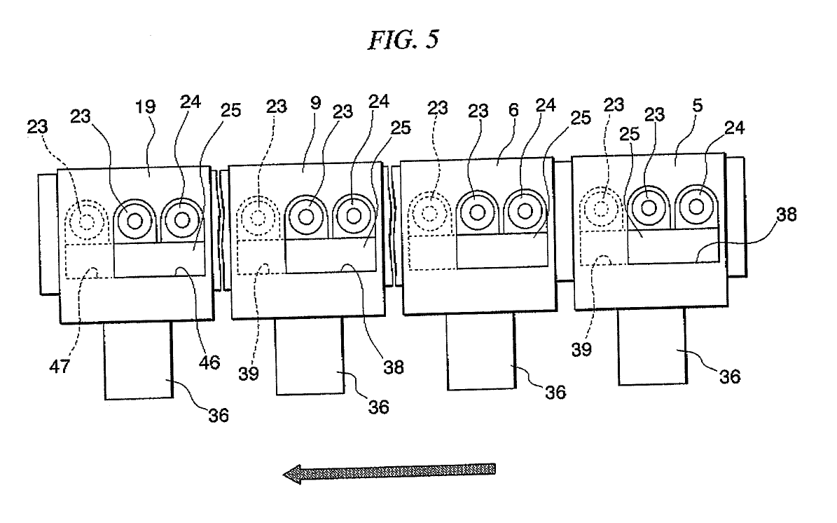

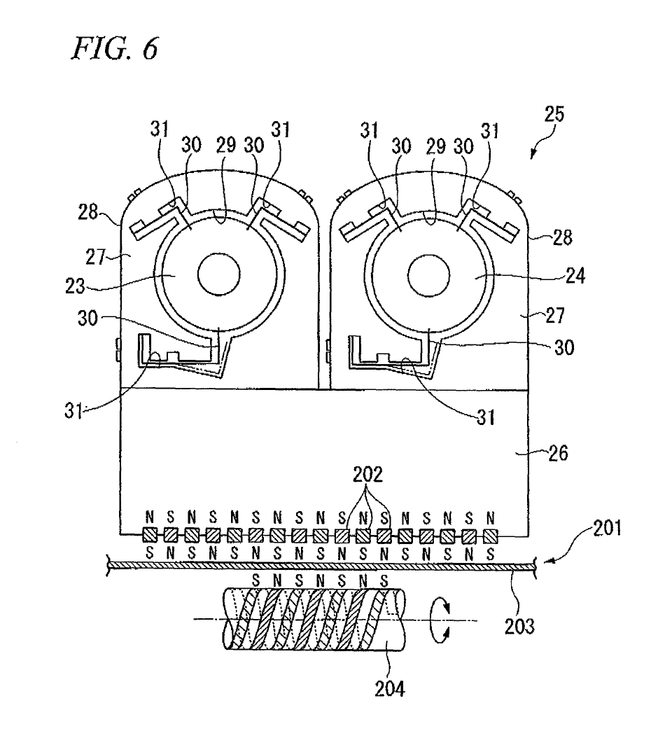

The carrier 25, as shown in FIGS. 5 and 6, has a supporting base 26, and a plurality of holders 27 provided on the upper surface of the supporting base 26. The holders 27 are provided parallel to each other on the upper surface of the supporting base 26 so that first and second film forming substrates 23 and 24 are held in a vertical arrangement (a state where the principal planes of the substrates 23 and 24 becomes parallel to the gravity direction), that is, so that the principal planes of the first and second film forming substrates 23 and 24 are substantially orthogonal to the upper surface of the supporting base 26, and become substantially flush therewith. In addition, since this embodiment has a configuration in which two holders 27 are mounted, each of two nonmagnetic substrates 80 to be held by the holders 27 shall be treated as a first film forming substrate 23 and a second film forming substrate 24.

Each holder 27 is configured such that circular holes 29 with a slightly larger diameter than the outer peripheries of the film forming substrates 23 and 24 are formed in plate bodies 28 having a thickness of about one or several times the thickness of the first and second film forming substrates 23 and 24.

Additionally, a plurality of the support members 30 is attached around the hole 29 of each holder 27 so as to be elastically deformable. The three supporting members 30 are provided side by side at regular intervals within an angle range of 120° around the hole 29 of the holder 27 so that the outer peripheral portion of the first or second film forming substrate 23 or 24 arranged inside the hole 29 is supported at three points including a lower fulcrum located at the lowest position on the outer periphery of the hole, and a pair of upper fulcrums located on the upper side on the outer periphery which become symmetrical with respect to a centerline along the gravity direction passing through the lower fulcrum.

Thereby, the carrier 25 can detachably hold the first or second film forming substrate 23 and 24 fitted inside the supporting members 30 by using the holder 27 while the outer peripheral portion of the first or second film forming substrate 23 and 24 is made to abut on the three supporting members 30. Additionally, the attachment or detachment of the first or second film forming substrate 23 and 24 to/from the holder 27 is performed as the above substrate supply robot 34 or the substrate detachment robot 49 depresses the supporting member 30 at the lower fulcrum.

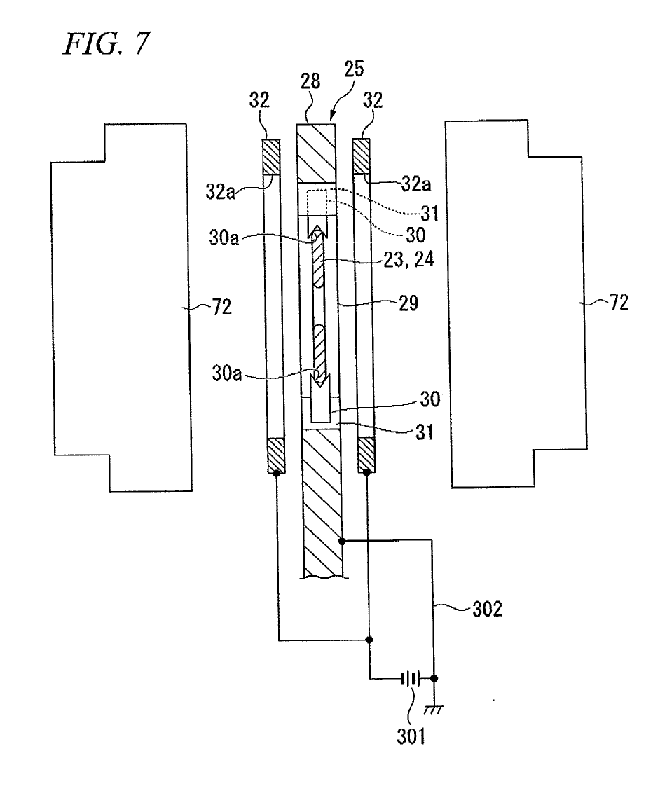

As shown in FIG. 6, each supporting member 30 has a spring member which bent in an L-shape, and is arranged in a slit 31 formed around the hole 29 of the holder 27 in a state where its proximal end is fixed to and supported by the holder 27, and its distal end protrudes toward the inside of the hole 29. Additionally, as shown in FIG. 7, the distal end of each supporting member 30 is provided with a V-shaped groove 30a which is engaged with the outer peripheral portion of the first or second film forming substrate 23 or 24.

As shown in FIG. 7, two treatment devices 72 are on both sides of the carrier 25 in the above-described chambers 5, 6, 8 to 13, 15, 16, and 18 to 20. In this case, film forming processing or the like is performed on the first film forming substrate 23 on the left of the carrier 25 in a state where the carrier 25 has stopped at a first treatment position shown by a solid line in FIG. 5. Thereafter, film forming processing or the like can be performed on the second film forming substrate 24 on the right of the carrier 25 in a state where the carrier 25 has moved to a second treatment position shown by a broken line in FIG. 5, and the carrier 25 has stopped at the second treatment position.

In addition, when four treatment devices 72 which face the first and second film forming substrates 23 and 24 are on both sides of the carrier 25, the movement of the carrier 25 becomes unnecessary, and forming processing or the like can be simultaneously performed on the first and second film forming substrates 23 and 24 held by the carrier 25.

The in-line film forming apparatus includes, for example, a linear motor drive mechanism 201 which drives the carrier 25 as shown in FIG. 6 in a noncontact state as a conveyor mechanism which conveys such a carrier 25. The conveyor mechanism 201 conveys the carrier 25 by arranging a plurality of magnets 202 in a lower part of the carrier 25 so that an N pole and an S pole are alternately aligned, arranging along a conveying path a rotary magnet 204 in which an N pole and an S pole are spirally and alternately aligned via a partition wall 203 below the magnets, and rotating the rotary magnet 204 around an axis while the magnets 202 on the side of the carrier 25 and the rotary magnet 204 are magnetically combined in non-contact.

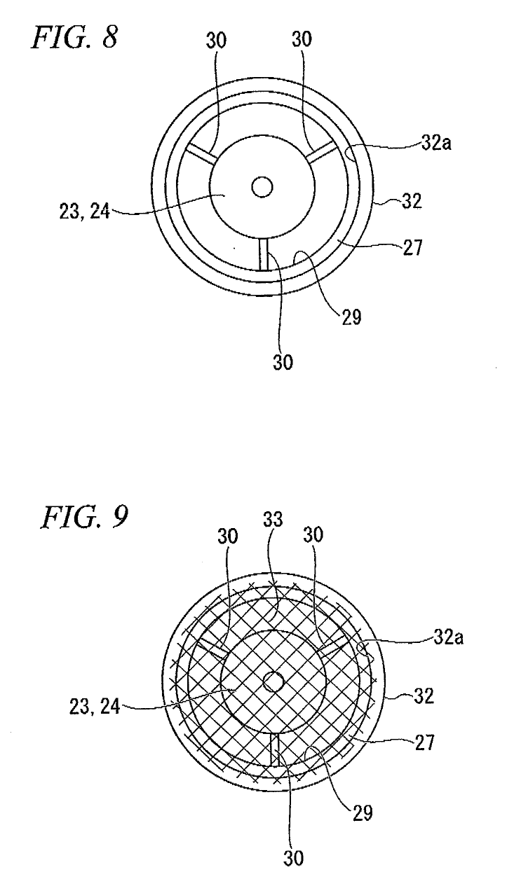

Meanwhile, the in-line film forming apparatus to which the invention is applied, as shown in FIGS. 7 and 8, includes a ring member 32 for preventing occurrence of uneven processing within the reforming chamber which performs reactive plasma treatment or ion irradiation treatment on the first and second film forming substrates 23 and 24 held by the carrier 25 described above.

This ring member 32 is made of, for example, stainless steel, molybdenum, tungsten, tantalum, etc., and a pair of the ring members is arranged to face both surfaces of the first or second film forming substrate 23 or 24 held by the carrier 28. Additionally, the pair of ring member 32 has an opening 32a with a larger diameter than the outer periphery of the substrate 23 or 24 in the position corresponding to the first or second film forming substrate 23 or 24.

Additionally, this reforming chamber is provided with a bias power source 301 which applies negative potential to the ring members 32. The bias power source 108 is a direct current power source in which a negative (−) electrode is connected to the pair of ring members 32, and a positive (+) electrode is connected to the holder 28, and applies negative potential to the pair of ring member 32 during reforming. Additionally, the holder 28 is grounded via a grounding conductor 302.

In the in-line film forming apparatus having the structure as described above, ions generated by the treatment device 72 within the reforming chamber are accelerated and made to collide against the first or second film forming substrate 23 or 24 through the opening 32a of the ring member 32 by applying negative potential to the pair of ring members 32. On the other hand, since the holder 28 is grounded, arcing does not occur in a contact portion between the first or second film forming substrate 23 or 24, and the supporting members 30. Accordingly, in this in-line film forming apparatus, it is possible to prevent occurrence of uneven processing when reactive plasma treatment or ion irradiation treatment is performed on the first and second film forming substrates 23 and 24 held by the carrier 25.

Additionally, in the in-line film forming apparatus to which the invention is applied, as shown in FIG. 9, in order to prevent the occurrence of uneven processing described above, it is also possible to adopt a configuration in which a mesh member 33 which covers the opening 32a is further attached to the ring member 32, In this case, ions generated by the treatment device 72 within the reforming chamber are evenly accelerated and made to collide against the first or second film forming substrate 23 or 24 through the opening 32a of the ring member 32 and the mesh member 33. Accordingly, in this configuration, it is possible to further prevent the occurrence of uneven processing In addition, it is preferable that a mesh member having a mesh interval within a range of 5 to 30 mm be used as the mesh member 33.

As described above, according to the invention, it is possible to provide an in-line film forming apparatus which prevents occurrence of uneven processing when reactive plasma treatment or ion irradiation treatment is performed on the first or second film forming substrate 23 or 24 held by the carrier 25. Accordingly, when such an in-line film forming apparatus is used, it is possible to enhance the productive capacity of magnetic recording media, and it is possible to manufacture high-quality magnetic recording media.

(Manufacturing Method of a Magnetic Recording Medium)

The manufacturing method of the magnetic recording medium to which the invention is applied manufactures a magnetic recording medium by using the above in-line film forming apparatus to laminate the magnetic layer 810 constituted by the soft magnetic layer 81, the interlayer 82, and the recording magnetic layer 83, and the protective layer 84 sequentially on both surfaces of the nonmagnetic substrate 80 while e first or second film forming substrate 23 or 24 (nonmagnetic substrate 80) held by the carrier 25 is conveyed through a plurality of chambers 2, 52, 4 to 20, 54, and 3A sequentially, and to form the lubricating layer 85 on the outermost surface.

Also, the manufacturing method of the magnetic recording medium to which the invention is applied includes the step of applying negative potential to the ring member 32 in a reforming chamber which performs the reactive plasma treatment or ion irradiation treatment after the recording magnetic layer 83 is formed as a film, and performing the reactive plasma treatment or ion irradiation treatment on the recording magnetic layer 83 of the nonmagnetic substrate 80 held by the holder 28 in a state where the holder 28 is grounded, thereby reforming the magnetic properties of a portion of the recording magnetic layer 83, preferably, reform the portion from a magnetic body into a nonmagnetic body to form the magnetic recording pattern 83a made of the remaining magnetic body.

Specifically, in this embodiment the manufacturing method includes a mounting step of mounting the nonmagnetic substrate 80 on which at least the recording magnetic layer 83 and the mask layer which patterns the recording magnetic layer 83 are laminated onto the carrier 25, a patterning step of patterning the mask layer, a reforming step of performing reactive plasma treatment or ion irradiation treatment on the region of the recording magnetic layer 83 which is not covered with the patterned mask layer, thereby reforming the region into a nonmagnetic body to form the magnetic recording pattern 83a, a removing step of removes the mask layer, a protective layer forming step of forming the protective layer 84 on the recording magnetic layer 83, and a detaching step of removing the nonmagnetic substrate 80 from the carrier in this order, and one or more of the reforming step, the removing step, or the protective layer forming step are 15 continuously performed in each one of a plurality of chambers.

Among the respective steps of this embodiment, the mounting step and the detaching step can be performed in a processing time of about one second per substrate.

However, the reforming step and removing step requires several tens of seconds, respectively, and the protective layer forming step requires the processing time of several seconds to about 30 seconds. When these steps are performed in one chamber for each step, the reforming step and the removing step become rate-determining steps, and consequently, it is necessary to tune the speed of the other steps to the speed of the reforming step and the removing step.

In this embodiment, the productivity of the magnetic recording media is improved by performing the steps whose processing speed becomes a rate-determining factor among the reforming step to the protective layer forming step in a plurality of chambers, thereby making the processing time between the respective steps as equal as possible. For example, when the processing time of the mounting step and of detaching step per one substrate in one chamber is 1 second, the processing time of the reforming step and the removing step is 60 seconds, and the processing time of the protective layer forming step is 30 seconds, the whole processing time when the chamber for each step is one is 60 seconds per substrate. Here, when the chambers for the reforming step and the removing step are set to two chambers, respectively, as in this embodiment, the processing time per one substrate becomes 30 seconds. Here, when the chambers for the reforming step and the removing step are set to four chambers, respectively, and the chambers for the protective layer forming step are set to two chambers, the processing time per one substrate becomes 15 seconds.

In the invention, it is preferable to simultaneously perform the above-described reactive plasma treatment or ion irradiation treatment on both the surfaces of the nonmagnetic substrate 80. This is because it is preferable to simultaneously treat both surfaces of a magnetic recording medium since the magnetic recording medium generally has the recording magnetic layer 83 on either surface thereof.

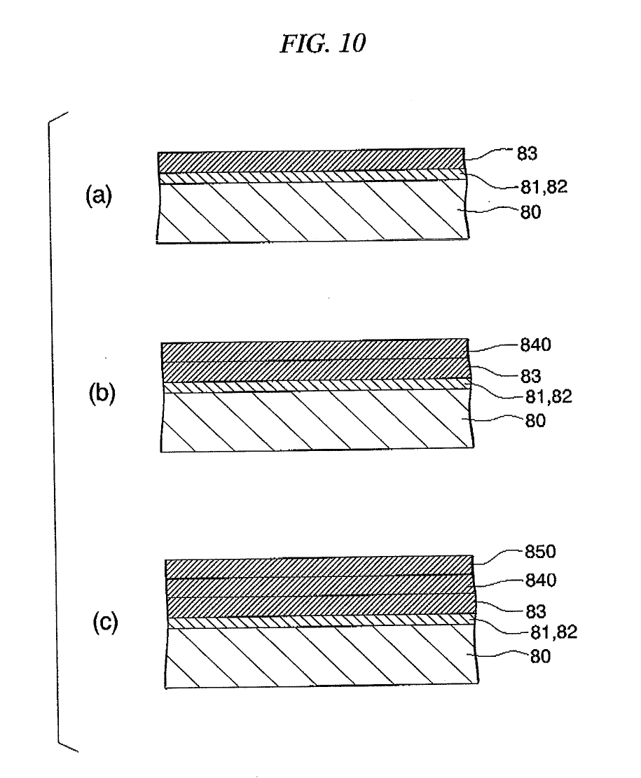

Typically, the recording magnetic layer 83 is formed as a thin film by a sputtering method. For example, as shown in FIGS 10(a) to 10(c), after the soft magnetic layer 81 and the interlayer 82 are sequentially laminated on the nonmagnetic substrate 80, the recording magnetic layer 83 is formed by at least a sputtering method (FIG. 10(a)), a mask layer 840 is then formed on the recording magnetic layer 83 (FIG. 10(b)), and a resist layer 850 is formed on the mask layer 840 (FIG. 10(c)).

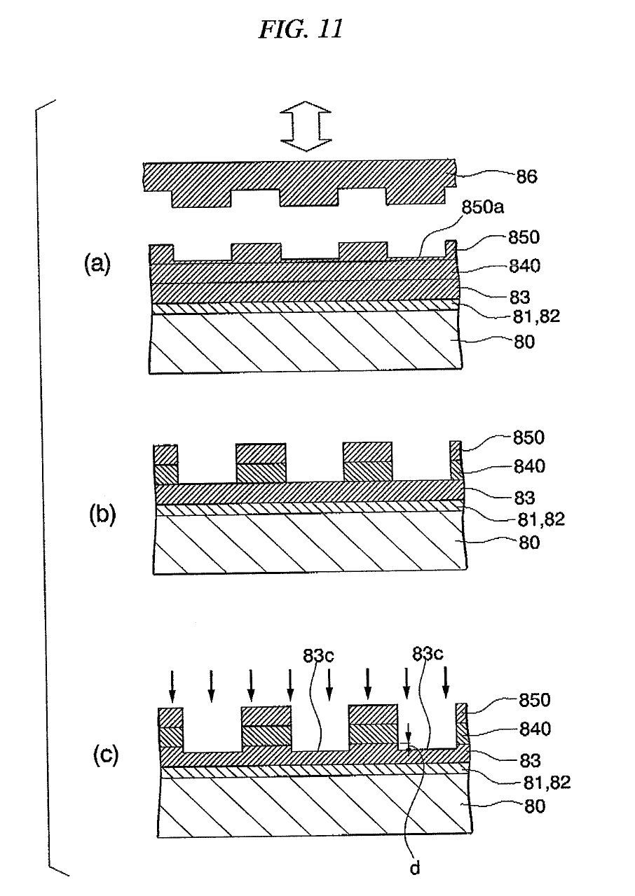

Next, as shown in FIG. 11, a negative pattern of the magnetic recording pattern 83a is transferred to the resist layer 850 using a stamp 86 (FIG. 11(a)). In addition the arrow in FIG. 11(a) shows the movement of a stamp 86.

Next, the nonmagnetic substrate 80 which has been processed so far is mounted on the carrier 25 in the above substrate attachment chamber 52. Then, the nonmagnetic substrate 80 is sequentially conveyed by the carrier 25, and a mask layer is patterned in the above two chambers (patterning chambers) 6 and 8 by using the resist layer 850 to which the negative pattern has been transferred (FIG. 11(b)).

Next, in the chamber 9, concave portions 83c are formed by partially ion-milling the surface of the recording magnetic layer 83 exposed by the patterning of the mask layer 840 (FIG. 11(c)). In addition, reference numeral d in FIG. 11(c) indicates the depth of the concave portions 83c provided in the recording magnetic layer 83.

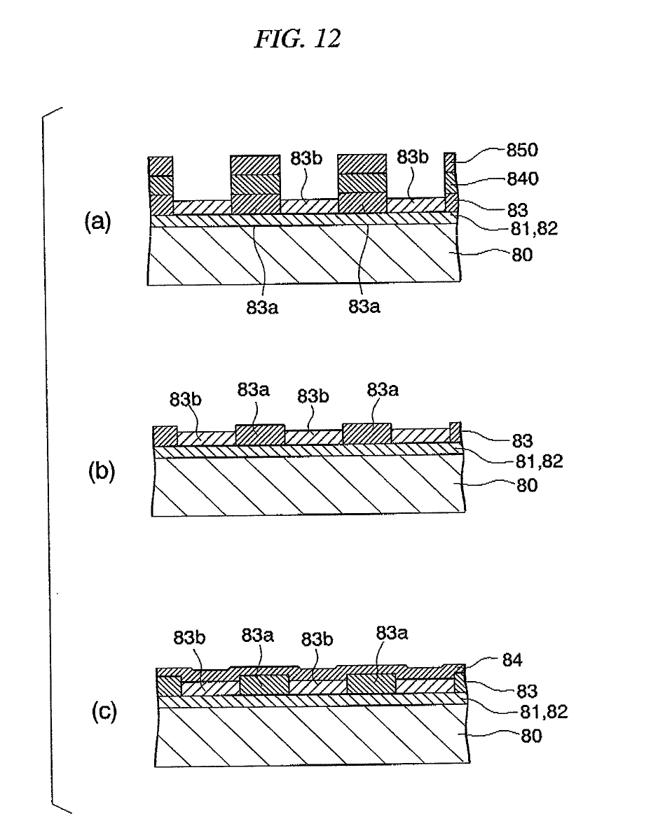

Next, as shown in FIG. 12, in the above three chambers (reforming chambers) 10, 11, and 12, a magnetic body which constitutes the recording magnetic layer 83 is reformed into a nonmagnetic body by performing reactive plasma treatment or ion irradiation treatment on the region of the recording magnetic layer 83 which is not covered with the mask layer 840 (FIG. 12(a)). This forms the magnetic recording pattern 83a and the nonmagnetic regions 83b in the recording magnetic layer 83, as shown in FIG. 12(a).

Next, in the above two chambers 13 and 15, the resist layer 850 is removed, and then, the mask layer 840 is removed in the two chambers (removal chamber) 16 and 18 (FIG. 12(b)).

Next, in the above two chambers 19 and 20, the surface of the recording magnetic layer 83 is covered with the protective layer 84 (FIG. 12(c)).

The magnetic recording medium of this embodiment can be manufactured by sequentially performing the above steps.

In addition, in the step in FIG. 10(b), as the mask layer 840 to be formed on the recording magnetic layer 83, it is preferable to form the mask layer from a material including at least one kind of element selected from a group consisting of Ta, W, Ta nitride, W nitride, Si, SiO₂, Ta₂O₅, Re, Mo, Ti, V, Nb, Sn, Ga, Ge, As, and Ni. By using such a material, the shielding performance against milling ions by the mask layer 840 can be improved, and the concave portions 83c can be provided in the recording magnetic layer 83.

Additionally, the formation properties of the magnetic recording pattern 83a by the mask layer 840 can be improved. Additionally, since these substances make dry etching using reactive gas easy, in the removing step of the mask layer 840 shown in FIG. 12(b), the amount of residue can be reduced, and contamination on the surface of a magnetic recording mediun can be reduced.

Additionally, as the mask layer 840, among these substances, it is preferable to use As, Ge, Sn, and Ga, it is more preferable to use Ni, Ti, V, and Nb, and it is most preferable to use Mo, Ta, and W.

Additionally, in the step shown in FIG. 11(a), it is preferable to set the thickness of a remaining portion 850a of the resist layer 850 after the transfer of the negative pattern to the resist layer 850 by the stamp 86 to be within a range of 0 to 10 nm.

In this case, by setting the thickness of the remaining portion 850a of the resist layer 850 to this range, in the patterning step of the mask layer 840 in FIG. 11(b), the sagging of an edge portion of the mask layer 840 can be eliminated, the shielding performance against ion milling by the mask layer 840 can be improved, and the concave portions 83c can be provided in the recording magnetic layer 83. Additionally, the formation properties of the magnetic recording pattern 83a by the mask layer 840 can be improved.

Additionally, it is preferable to use a material having hardenability by radiation exposure, as the constituent material of the resist layer 850, and to irradiate the resist layer 850 with radiations when a pattern is transferred to the resist layer 850 by using the stamp 86, or after the pattern transfer step.

By using such a manufacturing method, it is possible to transfer the shape of the stamp 86 to the resist layer 850 with high precision. As a result, in the patterning step of the mask layer 840 in FIG. 11(b), sagging of an edge portion of the mask layer 840 can be eliminated, the shielding performance of the mask layer 840 against implanted ions can be improved, and the formation properties of the magnetic recording pattern 83a by the mask layer 840 can be improved.

In addition, the radiations referred to here are electromagnetic waves of wide concepts, such as heat rays, visible light, ultraviolet rays, X rays, and gamma rays. Additionally, the material having hardenability by radiation exposure is, for example, a thermoset resin for heat rays or ultraviolet curable resin for ultraviolet rays.

In particular, in the step of transferring a pattern to the resist layer 850 by using the stamp 86, it is possible to transfer the shape of the stamp 86 to the resist layer 850 with high precision by presses the stamp against the resist layer 850 in a state where the fluidity of the resist layer is high, irradiating the resist layer 850 with radiations in the pressed state to curing the resist layer 850, and then, separating the stamp 86 from the resist layer 850.

As the methods of irradiating the resist layer 850 with radiations in a state where the stamp 86 is pressed against the resist layer 850, a method of irradiating the resist layer with radiations from the opposite side of the stamp 86, i.e., from the side of the nonmagnetic substrate 80, a method of selecting a substance which can transmit radiations as the constituent material of the stamp 86, and irradiate the resist layer with radiations from the side of the stamp 86, a method of irradiating the resist layer with radiations from the side surface of the stamp 86, and a method of irradiating the resist layer with radiations by the heat conduction via the stamp 86 or the nonmagnetic substrate 80 by using radiations having high conductivity to a solid like heat rays can be used.

Among these methods, it is particularly preferable to use an ultraviolet curable resin, such as a novolak-based resin, an acrylic ester, or an alicyclic epoxy, as the constituent material of the resist layer 850, and to use glass or resin having high transparency to ultraviolet rays as the constituent material of the stamp 86.

By using such methods, it is possible to reduce the coercive force and residual magnetization of the magnetic recording pattern 83a to a limit, it is possible to eliminate write blotting during magnetic recording, and it is possible to provide a magnetic recording medium with high surface recording density.

As the stamp 86 used in the above steps, for example, a stamp in which a fine track pattern is formed on a metal plate by using a method, such as electron beam lithography, can be used. As the material for the stamp, a material with the hardness and durability which can bear the steps are required. For example, although Ni or the like can be used, the material does not matter if it meets the afore-mentioned object A pattern of servo signals, such as a burst pattern, a gray code pattern, or a preamble pattern, other than a track which records normal data, can be formed on the stamp 86.

Additionally, in the above embodiment, as shown in FIG. 11(c), the concave portions 83c are provided by removing some of the surface layer of the recording magnetic layer 83 by ion milling or the like. Thus, when the concave portions 83c are provided, and the surfaces thereof are then exposed to reactive plasma or reactive ions, thereby reforming the magnetic properties of the recording magnetic layer 83, the contrast of a pattern between the magnetic recording pattern 83a and the nonmagnetic regions 83b becomes clearer, and the S/N of a magnetic recording medium can be improved, compared with the case where the concave portions 83c are not provided. For this reason, it is considered that the surface layer portion of the recording magnetic layer 83 is removed to clean and activate the surface thereof, and to increase the reactivity with the reactive plasma or reactive ions, and that defects, such as holes, are introduced into the surface layer portion of the recording magnetic layer 83, and the reactive ions easily penetrate the recording magnetic layer 83 through the defects.

Additionally, the depth d when a portion of the surface layer portion of the recording magnetic layer 83 is removed by ion milling or the like is set to be preferably within a range of 0.1 nm to 15 nm, and more preferably within a range of 1 to 10 nm. If the removal depth by ion milling is smaller than 0.1 nm, the removal effect of the recording magnetic layer 83 described above is not exhibited, and if the removal depth becomes greater than 15 nm, the surface smoothness of a magnetic recording medium deteriorates, and the floating characteristics of a magnetic head when a magnetic recording and reproducing apparatus is manufactured deteriorate.

This embodiment is characterized in that, for example, a region which magnetically separates a magnetic recording track and a servo signal pattern portion is formed by exposing a recording magnetic layer on which a film has already been formed to the reactive plasma or reactive ions, thereby reforming the magnetic properties of the recording magnetic layer.

In the invention, the magnetic recording pattern 83a, as shown in FIG. 12(a), indicates a pattern in a state where the magnetic properties of some of the recording magnetic layer 83 are reformed, preferably, the recording magnetic layer is separated by the nonmagnetic regions 83b which are made nonmagnetic, when the magnetic recording medium is seen from the surface side. That is, if the recording magnetic layer 83 is separated as seen from the surface side, even if the recording magnetic layer 83 is not separated at the bottom thereof it is possible to achieve the object of the invention, and this configuration is also included in the concept of the magnetic recording pattern 83a in the invention. Additionally, the magnetic recording pattern 83a in the invention includes so-called patterned media in which the magnetic recording pattern is arranged with fixed regularity per one bit, the media in which the magnetic recording pattern is arranged in the shape of a track, or the other patterns such as servo signal patterns.

Among them, it is preferable from the simplicity in manufacture that the invention is applied to a discrete magnetic recording medium in which the magnetic recording pattern 83a is a magnetic recording track and a servo signal pattern.

Additionally, the reforming of the recording magnetic layer 83 for forming the magnetic recording pattern 83 a refers to partially changing the coercive force, residual magnetization, etc. of the recording magnetic layer 83 in order to pattern the recording magnetic layer 83, and the change refers to lowering the coercive force, and lowering the residual magnetization.

In particular, as for the reforming of the magnetic properties, it is preferable to adopt a method of setting the amount of magnetization of the recording magnetic layer 83 in the region exposed to the reactive plasma or reactive ion to 75% or less, and more preferably 50% or less than the original untreated value, and setting the coercive force to 50% or less, and more preferably 20% or less, the original value. By manufacturing a discrete track type magnetic recording medium using the above-metioned method, write blotting when magnetic recording is performed on this medium can be eliminated, and it is possible to provide a magnetic recording medium with high surface recording density.

Additionally, in the invention, regions (nonmagnetic regions 83b) which separate a magnetic recording track and a servo signal pattern portion can also be realized by exposing a recording magnetic layer on which a film has already been formed to the reactive plasma or reactive ions, thereby making the recording magnetic layer 83 amorphous. That is, the reforming of the magnetic properties of the recording magnetic layer in the invention also includes realization by the alteration of the crystal structure of a recording magnetic layer.

In the invention, making the recording magnetic layer 83 amorphous refers to making the atomic arrangement of the recording magnetic layer 83 into the irregular atomic arrangement which does not have long-distance order, and more specifically, refers to arranging microcrystal grains less than 2 nm at random. When this atomic arrangement state is verified by an analytical method, a peak showing a crystal face is not observed and only a halo is observed, by X-ray diffraction or electron diffraction.

The reactive plasma can be exemplified by, inductively coupled plasma (ICP) and reactive ion plasma (RIE). Additionally, the reactive ions which exist in the inductively coupled plasma or reactive ion plasma as described above can be exemplified as the reactive ions.

The inductively coupled plasma can be exemplified by, the high-temperature plasma obtained by applying a high voltage to gas, thereby forming plasma, and generating the Joule's heat by an eddy current inside the plasma by a varying the magnetic field of high frequency. The inductively coupled plasma has high electron density, and can realize the reforming of magnetic properties at high efficiency in a magnetic film with a large area compared with a conventional case where discrete track media are manufactured using an ion beam.

The reactive ion plasma is the highly reactive plasma in which a reactive gas, such as O₂, SF₆, CHF₃, CF₄, or CCl₄ is added into the plasma. By using such a plasma, it is possible to realize the reforming of the magnetic properties of the recording magnetic layer 83 with a higher efficiency.

In the invention, the recording magnetic layer 83 is reformed by exposing the recording magnetic layer 83 on which a film has been formed to the reactive plasma. However, it is preferable that this reforming be realized by the reaction between magnetic metal which constitutes the recording magnetic layer 83, and atoms or ions in the reactive plasma.

In this case, a reaction in which atoms or the like in the reactive plasma penetrate a magnetic metal, and the crystal structure of the magnetic metal changes, a reaction in which the composition of a magnetic metal changes, a reaction in which a magnetic metal oxidizes, a reaction in which a magnetic metal nitrides, a reaction in which a magnetic metal silicifies, and so on can be exemplified as the reaction.

In particular, it is preferable to make oxygen atoms contained in reactive plasma, and make a magnetic metal which constitutes the recording magnetic layer 83, and the oxygen atoms in the reactive plasma react with each other, thereby oxidizing the recording magnetic layer 83. This is because it is possible to partially oxidize the recording magnetic layer 83 to efficiently reduce the residual magnetization, coercive force, and so on of an oxidized portion, and it is therefore possible to manufacture a magnetic recording medium which has a magnetic recording pattern by short-time reactive plasma treatment.

Additionally, it is preferable to make the halogen atoms contained in the reactive plasma. In particular, it is preferable to use F atoms as the halogen atoms. The halogen atoms may be used after being added into the reactive plasma together with oxygen atoms, or may be added into the reactive plasma, without using oxygen atoms. As described above, it is possible to add oxygen atoms or the like to the reactive plasma, thereby making a magnetic metal which constitutes the recording magnetic layer 83, and oxygen atoms or the like react with each other to reform the magnetic properties of the recording magnetic layer 83. At this time, it is possible to make the halogen atoms contained in the reactive plasma to further enhance this reactivity.

Additionally, even when the oxygen atoms are not added into the reactive plasma, the halogen atoms reacts with a magnetic alloy, and thus, the magnetic properties of the recording magnetic layer 83 can be reformed. Although the details of this reason are not clear, it is considered that the halogen atoms in the reactive plasma etch foreign matters formed on the surface of the recording magnetic layer 83, thereby cleaning the surface of the recording magnetic layer 83, and enhancing the reactivity of the recording magnetic layer 83.

Additionally, it is considered that the cleaned magnetic layer surface and the halogen atoms react with each other with high efficiency. It is especially preferable to use F atoms as the halogen atoms having such an effect.

In this embodiment, thereafter, it is preferable to adopt a step of removing the resist layer 850 and the mask layer 840 as shown in FIG. 12(b), then removing the protective layer 84 as shown in FIG. 12(c), and applying a lubricant (not shown) to manufacture a magnetic recording medium.

For the removal of the resist layer 850 and he mask layer 840, a technique, such as dry etching, reactive ion etching, ion mill, or wet etching, can be used.

Although a method of forming a diamond-like carbon thin film by using P-CVD or the like is generally for the formation of the protective layer 84, the invention is not particularly limited thereto. In this case, as the protective layer 84, carbonaceous layers, such as carbon (C), hydrogenated carbon (HₓC), nitrogenated carbon (CN), armorphous carbon, and silicon carbide (SiC), or protective layer materials, which are usually used, such as SiO₂, Zr₂O₃, and TIN, can be used. Additionally, the protective layer 84 may be composed of two or more layers.

The film thickness of the protective layer 84 needs to be less than 10 nm. This is because, if the film thickness of the protective layer 84 exceeds 10 nm, the distance between a head and the recording magnetic layer 83 becomes large, and sufficient input/output signal intensity is not obtained.

It is preferable to form the lubricating layer 85 on the protective layer 84. The lubricant used for the lubricating layer 85,can be exemplified by fluorine-based lubricant, hydrocarbon-based lubricant, and mixtures thereof, and the lubricating layer 85 is usually formed with a thickness of 1 to 4 nm.

According to the above manufacturing method and manufacturing apparatus, the reforming of the magnetic recording layer 83 to the formation of the protective layer 84 can be continuously performed using one apparatus, a processing substrate is not contaminated when the processing substrate is handled, the number of handling step and the like can be reduced to enhance the efficiency of the manufacturing process, and the yield of products can be improved to enhance the productivity of magnetic recording media.

Additionally, according to the above manufacturing method and manufacturing apparatus, a step of exposing the region of a recording magnetic layer which is not covered with a mask layer to the reactive plasma or the like, thereby reforming the magnetic properties of this region, and a step of removing the mask layer are shared and performed in a plurality of chambers. Thus, these processes can be easily introduced into an in-line film forming apparatus.

That is, the film forming step for a recording magnetic layer and the like can be processed in a time period of about 10 seconds per one substrate, whereas it is difficult to process the step of partially reforming the magnetic properties of a recording magnetic layer, and the step of removing a mask layer in this time period. Therefore, the reforming step and removing step are shared and performed by a plurality of chambers, respectively, so that the processing time of these steps can be tuned to the processing time of the film forming step for a recording magnetic layer and the like, and thereby, the respective steps can be continuously performed.

Additionally, a wet step of applying a liquid resist to the surface of a recording magnetic layer, and stamping a mould onto the surface of the resist to transfer a mould pattern is included in the step of patterning the mask layer on the surface of the recording magnetic layer. In the above manufacturing method and manufacturing apparatus, since all the steps other than the application of the resist are performed in a wet step, the steps can be continuously performed in one manufacturing apparatus in combination with a sputtering step of the recording magnetic layer which is similarly a dry step.

### EXAMPLES

Now, the effects of the invention will be more apparent by examples. In addition, the invention is not limited to the following example, and can be suitably changed and carried out without departing from the concept of the invention.

### Example 1

In Example 1, first, a glass substrate for HD was prepared as a nonmagnetic substrate, and a vacuum chamber in which the glass substrate was set was evacuated to 1.0×10⁻⁵ or less Pa in advance. The material of the glass substrate used here is crystallized glass including Li₂Si₂O₅, Al₂O₃-K₂O, MgO-P₂O₅, and Sb₂O₃-ZnO as its constituent. The external diameter of this glass substrate is 65 mm, the internal diameter thereof is 20 mm, and the average surface roughness (Ra) is 2 Å.

Next, magnetic layers were formed on both surfaces of the glass substrate by laminating FeCoB as a soft magnetic layer, Ru as an interlayer, and 70Co-5Cr-15Pt-10SiO₂ alloy as a recording magnetic layer in this order by using a DC sputtering method for this glass substrate. As the thickness of the respective layers, the soft magnetic layer was set to 600 Å, the interlayer was set to 100 Å, and the recording magnetic layer was set to 150 Å.

Next, a mask layer was formed on the magnetic layer by a sputtering method. The mask layer was formed using Ta such that the film thickness thereof is 60 nm. Then, a resist layer was formed by applying a resist onto this mask layer by a spin coat method. A novolak-based resin which is ultraviolet curable resin was used as the resist, and the thickness of the resist layer was set to 100 nm.

Next, a glass stamp which has a negative pattern of a magnetic recording pattern was prepared, and his stamp was pressed against the resist layer by the pressure of 1 MPa (about 8.8 kgf/cm²). Then, in his state, ultraviolet rays with a wavelength of 250 nm were radiated for 10 seconds from an upper portion of the glass stamp of which the transmittance of ultraviolet rays is 95% or more, and the resist layer was hardened. Thereafter, a rugged pattern corresponding to the magnetic recording pattern was transferred to the resist layer by separating the stamp from the resist layer.

In addition, the rugged pattern transferred to the resist layer has a circumferential shape in which the width of a convex portion is 120 nm, and the width of a concave portion is 60 nm. Additionally, the thickness of the resist layer after the hardening was 80 nm, and the thickness of the remaining portion which constitutes the concave portion of the resist layer was about 5 nm. Additionally, the angle of a side wall surface which constitutes the concave portion of the resist layer with respect to the substrate surface was about 90 degrees.

The processing substrate manufactured as described above was supplied to the in-line film forming apparatus of the invention shown in FIG. 4. Then, this apparatus was configured so that the step of mounting the processing substrate onto the carrier 25 was performed in one processing chamber 52, the removal of the remaining portion of the concave portion of the resist layer was performed in one processing chamber 5, the patterning step of the mask layer was performed in the two processing chambers 6 and 8 (pattering chambers), and the step of partially removing the surface of the recording magnetic layer was performed in one processing chamber 9. Additionally, this apparatus was configured so that the step of partially reforming the recording magnetic layer was performed in the three processing chambers 10, 11, and 12 (reforming chambers), the step of removing the resist was performed in the two chambers 13 and 15, the step of removing the mask layer was performed in the two processing chambers 16 and 18 (removal chambers), and the film forming step of a carbon protective layer was performed in the two processing chambers 19 and 20 (protective layer forming chambers). Moreover, this apparatus was configured so that the step of detaching the processing substrate from the carrier 25 was performed in one processing chamber 54. In addition, the processing time in each chamber was realized in 15 seconds.

Here, in the removal chamber, as shown in FIG. 9, the pair of ring members 32 to which the mesh member 33 was attached was arranged in the positions where they face on both surfaces of the processing substrate, and in the processing in this removal chamber, the processing substrate was grounded, and a negative DC bias was applied to the pair of ring members 32 from an ion source or a plasma source. In addition, the ring members 32 are made of SUS304, the internal diameter thereof is 80 mm, and the thickness thereof is 2 mm. The mesh member 33 is one obtained by arranging a wire with a diameter of 0.3 mm made of SUS304 in the shape of a mesh, and the mesh spacing is 20 mm. Additionally, the distance between the pair of ring members and the processing substrate was about 8 mm.

Hereinafter, the details of the respective steps will be described. First, in the step of mounting the processing substrate onto the carrier 25, the processing substrate was mounted onto the carrier 25 at a speed of 1.5 seconds/sheet in the chamber 52.

Next, in the removing step of the concave portion of the resist layer, the carrier 25 on which the processing substrate has been mounted was rotated in the corner chamber 4 and moved to the processing chamber 5, and the region of the concave portion of the resist layer removed by dry etching within the processing chamber 5. As for the etching of the resist layer in the dry etching conditions, O₂ gas was set to 40 sccm, the pressure was set to 0.3 Pa, the high-frequency plasma power was set to 300 W, the DC bias was set to 30 W, and the etching time was set to 15 seconds.

Next, in the patterning step of the mask layer, the processing substrate which was subjected to etching processing was moved to the two processing chambers 6 and 8 which perform the patterning step of the mask layer sequentially, and the region in the mask layer of Ta which is not covered with the resist was removed within the processing chambers 6 and 8 by dry etching. As for the etching of the resist layer in the dry etching conditions, O₂ gas was set to 40 sccm, the pressure was set to 0.3 Pa, the high-frequency plasma power was set to 300 W, the DC bias was set to 30 W, and the etching time was set to 10 seconds, and as for the etching of the mask layer CF₄ gas was set to 50 sccm, the pressure was set to 0.6 Pa, the high-frequency plasma power was set to 500 W, the DC bias was set to 60 W, and the etching time was set to 15 seconds per one chamber, and to 30 seconds in total.

Next, in the step of partially removing the surface of the recording magnetic layer, the processing substrate which was subjected to dry etching was moved to the processing chamber 9 which partially removes the recording magnetic layer, and the surface of the recording magnetic layer was removed by ion milling in a region of the recording magnetic layer which was not covered with the mask layer within the processing chamber 9. Ar ions were used for ion milling, the amount of ions was set to 5×10¹⁶ atoms/cm², the acceleration voltage between an ion source and the ring members was set to 20 keV, the milling depth of the recording magnetic layer was set to 0.1 nm, and the ion milling time was set to 5 seconds.

Next, in the step of partially reforming the surface of the recording magnetic layer, the processing substrate which was subjected to ion milling was moved to the three processing chambers 10, 11, and 12 which partially reform the recording magnetic layer sequentially, and the surface of the region of the recording magnetic layer which was not covered with the mask layer was exposed to the reactive plasma, thereby performing reforming of magnetic properties. An inductively-coupled-plasma apparatus made by Ulvac, Inc. was used for the reactive plasma treatment of the recording magnetic layer. As the gas and conditions used for the generation of the plasma, O₂ (90 cc/min) was used, the electric power supplied for generation of plasma was set to 200 W, the pressure within the chamber was set to 0.5 Pa, and the processing time for the magnetic layer was set to 15 seconds per one chamber, and set to 45 seconds in total.

Next, in the step of removing the resist layer, the processing substrate which was subjected to reforming was moved to the two processing chambers 13 and 15 which perform the resist layer, and the resist layer was removed by dry etching within the processing chambers 13 and 15. As for the etching of the resist layer in the dry etching conditions, O₂ gas was set to 40 sccm, the pressure was set to 0.3 Pa, the high-frequency plasma power was set 300 W, the DC bias was set to 30 W, and the etching time was set to 15 seconds.

Next, in the step of removing the mask layer, the processing substrate of which the resist layer was removed was moved to the two processing chambers 16 and 18 which remove the mask layer, and the mask layer was removed by dry etching within the processing chambers 16 and 18. As for the etching of the resist layer in the dry etching conditions, O₂ gas was set to 40 sccm, the pressure was set to 0.3 Pa, the high-frequency plasma power was set 300 W, the DC bias was set to 30 W, and the etching time was set to 10 seconds, and as for the etching of the Ta layer, CF₄ gas was set to 50 sccm, the pressure was set to 0.6 Pa, the high-frequency plasma power was set 500 W, the DC bias was set to 60 W, and the etching time was set to 15 seconds per one chamber, and set to 30 seconds in total.

Next, in the step of forming the carbon protective layer, the processing substrate of which the mask layer was removed was moved to the two processing chambers 19 and 20 sequentially, and a carbon protective layer of 5 nm was formed on the magnetic layer within the processing chambers 19 and 20 by the CVD method. The film forming time was set to 15 seconds.

Next, in the step of detaching the processing substrate from the carrier 25, the processing substrate which was subjected to film forming processing was moved to the processing chamber 54 detached from the carrier 25, and the processed substrate was detached from the carrier 25 at a speed of 1.5 seconds/sheet within the processing chamber 54.

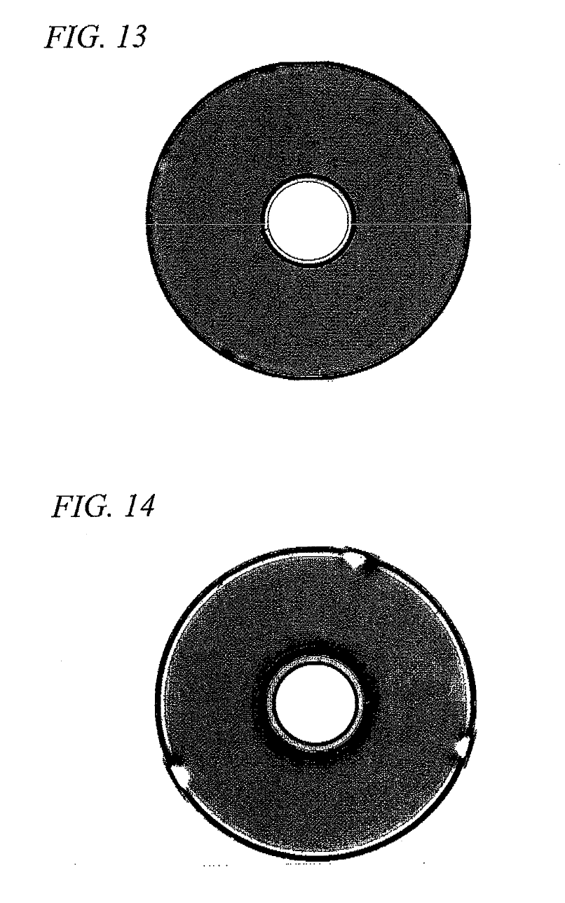

The magnetic recording medium of Example 1 was manufactured by passing through the above manufacturing steps. An optical microscope photograph obtained by photographing the magnetic recording medium of Example 1 is shown in FIG. 13.

As shown in FIG. 13, in the magnetic recording medium of Example 1, it can be seen that uneven processing is hardly generated near the outer periphery of a substrate, and a good film forming state is maintained in a plane.

### Comparative Example 1

In Comparative Example 1, a magnetic recording medium was manufactured similarly to Example 1 in the above removal chamber except for a configuration in which a pair of ring member 32 to which the mesh member 33 is attached is not disposed. An optical microscope photograph obtained by photographing the magnetic recording medium of Comparative Example 1 is shown in FIG. 14.

As shown in FIG. 14, in the magnetic recording medium of Comparative Example 1, it can be seen that uneven processing occurs near the outer periphery of the nonmagnetic substrate which abuts the support member.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. An in-line film forming apparatus comprising:
a plurality of chambers which perform film forming processing;
a carrier which holds a substrate to be used as an object to be film-formed within the plurality of chambers; and
a conveyor mechanism which conveys the carrier sequentially between the plurality of chambers,
wherein the carrier includes a holder provided with a hole which allows the substrate to be disposed therein, and a plurality of supporting members attached to the periphery of the hole of the holder in an elastically deformable manner, and is capable of detachably holding the substrate fitted into the inside of the supporting members while an outer peripheral portion of the substrate is made to abut on the plurality of supporting members,
wherein at least one of the plurality of chambers is a chamber which performs the reactive plasma treatment or ion irradiation treatment on the substrate held by the carrier, and a ring member having an opening in a position corresponding to the substrate is disposed within the chamber so as to face at least one surface or both surfaces of the substrate held by the carrier, and
wherein negative potential is applied to the ring member, and the holder is grounded.

2. The in-line film forming apparatus according to claim 1,
wherein a mesh member which covers the opening is attached to the ring member.

3. The in-line film forming apparatus according to claim 1,
wherein the tip of each of the plurality of supporting members is provided with a groove engaged with the outer peripheral portion of the substrate.

4. The in-line film forming apparatus according to claim 2,
wherein the tip of each of the plurality of supporting members is provided with a groove engaged with the outer peripheral portion of the substrate.

5. A manufacturing method of a magnetic recording medium which forms at least a soft magnetic layer, an interlayer, and a recording magnetic layer, and a protective layer sequentially on both surfaces of a nonmagnetic substrate while the nonmagnetic substrate held by the carrier is conveyed through the plurality of chambers sequentially, using the above in-line film forming apparatus according to claim 1, the manufacturing method comprising the step of:
applying a negative potential to the ring member in a chamber which performs the reactive plasma treatment or ion irradiation treatment after the recording magnetic layer is formed as a film, and performing the reactive plasma treatment or ion irradiation treatment on the recording magnetic layer of the nonmagnetic substrate held by the holder in a state where the holder is grounded, thereby reforming the magnetic properties of a portion of the recording magnetic layer, and forming a magnetic recording pattern made of the remaining magnetic body.

6. A manufacturing method of a magnetic recording medium which forms at least a soft magnetic layer, an interlayer, and a recording magnetic layer, and a protective layer sequentially on both surfaces of a nonmagnetic substrate while the nonmagnetic substrate held by the carrier is conveyed through the plurality of chambers sequentially, using the in-line film forming apparatus according to claim 2, the manufacturing method comprising the step of:
applying negative potential to the ring member in a chamber which performs the reactive plasma treatment or ion irradiation treatment after the recording magnetic layer is formed as a film, and performing the reactive plasma treatment or ion irradiation treatment on the recording magnetic layer of the nonmagnetic substrate held by the holder in a state where the holder is grounded, thereby reforming the magnetic properties of a portion of the recording magnetic layer, and forming a magnetic recording pattern made of the remaining magnetic body.

7. A manufacturing method of a magnetic recording medium which forms at least a soft magnetic layer, an interlayer, and a recording magnetic layer, and a protective layer sequentially on both surfaces of a nonmagnetic substrate while the nonmagnetic substrate held by the carrier is conveyed through the plurality of chambers sequentially, using the in-line film forming apparatus according to claim 3, the manufacturing method comprising the step of:
applying a negative potential to the ring member in a chamber which performs the reactive plasma treatment or ion irradiation treatment after the recording magnetic layer is formed as a film, and performing the reactive plasma treatment or ion irradiation treatment on the recording magnetic layer of the nonmagnetic substrate held by the holder in a state where the holder is grounded, thereby reforming the magnetic properties of a portion of the recording magnetic layer, and forming a magnetic recording pattern made of the remaining magnetic body.

8. A manufacturing method of a magnetic recording medium which forms at least a soft magnetic layer, an interlayer, and a recording magnetic layer, and a protective layer sequentially on both surfaces of a nonmagnetic substrate while the nonmagnetic substrate held by the carrier is conveyed through the plurality of chambers sequentially, using the in-line film forming apparatus according to claim 4, the manufacturing method comprising the step of:
applying a negative potential to the ring member in a chamber which performs the reactive plasma treatment or ion irradiation treatment after the recording magnetic layer is formed as a film, and performing the reactive plasma treatment or ion irradiation treatment on the recording magnetic layer of the nonmagnetic substrate held by the holder in a state where the holder is grounded, thereby reforming the magnetic properties of a portion of the recording magnetic layer, and forming a magnetic recording pattern made of the remaining magnetic body.
